(19) United States
(12) Patent Application Publication
(10) Pub. No.: US 2014/0238462 A1
(43) Pub. Date: Aug. 28, 2014

(54) SOLAR CELL MODULE

(71) Applicant: LG ELECTRONICS INC., Seoul (KR)

(72) Inventors: Daehee JANG, Seoul (KR); Bojoong KIM, Seoul (KR); Taeyoon KIM, Seoul (KR); Minpyo KIM, Seoul (KR)

(73) Assignee: LG ELECTRONICS INC., Seoul (KR)

(21) Appl. No.: 14/175,157

(22) Filed: Feb. 7, 2014

(30) Foreign Application Priority Data
Feb. 27, 2013 (KR) 10-2013-0020930

(51) Int. Cl. H01L 31/05

(52) U.S. Cl. CPC H01L 31/0508
USPC 136/244

(57) ABSTRACT

A solar cell module is discussed. The solar cell module includes a plurality of solar cells, an interconnector for electrically connecting the adjacent solar cells, and a conductive adhesive film for attaching the interconnector to the solar cell. Each solar cell includes a substrate, a back electrode part including a plurality of back electrode current collectors of an island shape, which are positioned on a back surface of the substrate and are separated from one another by a first distance along a first direction, and a back electrode which includes a plurality of openings exposing the back electrode current collectors and has a sheet shape covering the entire back surface of the substrate. The conductive adhesive film alternately includes a first portion contacting the back electrode current collector and a second portion contacting the back electrode based on the first direction.

This application claims priority to and the benefit of Korean Patent Application No. 10-2013-0020930 filed in the Korean Intellectual Property Office on Feb. 27, 2013, the entire contents of which are incorporated herein by reference.

### BACKGROUND OF THE INVENTION

1. Field of the Invention

Embodiments of the invention relate to a solar cell module, in which adjacent solar cells are electrically connected to one another using an interconnector.

2. Description of the Related Art

Solar power generation to convert light energy into electric energy using a photoelectric conversion effect has been widely used as a method for obtaining eco-friendly energy. A solar power generation system using a plurality of solar cell modules has been installed in places, such as houses, due to an improvement in a photoelectric conversion efficiency of solar cells.

In the solar cell module, a method for connecting conductors (for example, interconnectors) connected to an anode and a cathode of the solar cell using lead lines to get out of the solar cell module and connecting the lead lines to a junction box to obtain an electric current through power supply lines of the junction box is used to output electric power generated by the solar cell to the outside.

### SUMMARY OF THE INVENTION

In one aspect, there is a solar cell module including a plurality of solar cells each including a substrate, a back electrode part including a plurality of back electrode current collectors of an island shape, which are positioned on a back surface of the substrate and are separated from one another by a first distance along a first direction, and a back electrode which includes a plurality of openings exposing the plurality of back electrode current collectors and has a sheet shape covering the entire back surface of the substrate, an interconnector configured to electrically connect adjacent solar cells, and a conductive adhesive film configured to attach the interconnector to the solar cells, wherein the back electrode current collectors and the back electrode are formed of different metal materials, and wherein the conductive adhesive film alternately includes a first portion contacting the back electrode current collector and a second portion contacting the back electrode based on the first direction.

The back electrode and the back electrode current collectors may overlap or may not overlap each other at edges of the openings of the back electrode.

A thickness of the back electrode may be greater or less than a thickness of the back electrode current collector. A difference between the thickness of the back electrode and the thickness of the back electrode current collector may be about 5 μm to 25 μm.

A thickness of the first portion of the conductive adhesive film may be greater or less than a thickness of the second portion of the conductive adhesive film. A difference between the thicknesses of the first portion and the second portion of the conductive adhesive film may be about 5 μm to 25 μm.

The conductive adhesive film may further include a third portion contacting the back electrode on at least one side of the first portion in a second direction orthogonal to the first direction.

Each solar cell may further include a back surface field region positioned at the back surface of the substrate. The back surface field region may be positioned only in a formation area of the back electrode, or may be positioned in a formation area of the back electrode and a formation area of the openings of the back electrode.

When the back surface field region is positioned only in the formation area of the back electrode, the back surface field region is not positioned in the formation area of the openings of the back electrode.

The conductive adhesive film may include a resin and a plurality of conductive particles distributed in the resin, and the plurality of conductive particles may directly contact the interconnector and one of the back electrode and the back electrode current collector.

Each solar cell may further includes an emitter region positioned at an entire front surface of the substrate, a front electrode part electrically connected to the emitter region, and a dielectric layer positioned on the emitter region. The front electrode part may include a plurality of finger electrodes extending in the second direction orthogonal to the first direction, and an entire lower surface of each finger electrode may directly contact the emitter region.

The front electrode part may further include a front electrode current collector which extends in the first direction and is connected to the plurality of finger electrodes, and an entire lower surface of the front electrode current collector may directly contacts the emitter region.

The plurality of openings may respectively correspond to the plurality of back electrode current collectors.

When the back electrode current collector and the back electrode are formed of different metal materials, aluminum (Al) capable of forming the back surface field region at the back surface of the substrate in a firing process is generally used as a material of the back electrode, and silver (Ag) having more excellent conductivity than aluminum (Al) is generally used as a material of the back electrode current collector.

However, the adhesive characteristic of the conductive adhesive film greatly changes depending on kinds of metals to be attached in an existing tin (Sn)-based solder, and the adhesive characteristic between the conductive adhesive film and the back electrode formed of aluminum (Al) is very bad.

Accordingly, when the back electrode current collector and the back electrode are formed of different metal materials, the existing tin (Sn)-based solder is satisfactorily attached to the back electrode current collector formed of silver (Ag), but is unsatisfactorily attached to the back electrode formed of aluminum (Al).

Hence, because the interconnector is electrically connected only to the back electrode current collector, a current collection efficiency is reduced.

Further, when the thickness of the back electrode current collector positioned in the opening of the back electrode is less than the thickness of the back electrode and thus a height difference between a front surface of the back electrode and a front surface of the back electrode current collector is generated at the edge of the opening, a space between the front surface of the back electrode current collector and the interconnector is not fully filled with the solder. Therefore, the interconnector does not contact the back electrode current collector in a portion having the height difference, and a non-attachment portion of the interconnector is generated. Hence, the current collection efficiency is further reduced.

However, the conductive adhesive film may be attached to the back electrode formed of aluminum (Al) as well as the back electrode current collector formed of silver (Ag).

Further, even when the thickness of the back electrode current collector positioned in the opening of the back electrode is less than the thickness of the back electrode and thus a height difference between a front surface of the back electrode and a front surface of the back electrode current collector is generated at the edge of the opening, a space between the front surface of the back electrode current collector and the interconnector is fully filled because the conductive adhesive film has the flexibility by performing a tabbing process using the conductive adhesive film. Therefore, a non-attachment portion between the back electrode current collector and the interconnector is not generated. Hence, a reduction in the current collection efficiency may be prevented or reduced.

Accordingly, even when the plurality of back electrode current collectors are positioned in the island shape along a longitudinal direction of the conductive adhesive film in an area to which the conductive adhesive film is attached, the current collection efficiency of the solar cell module may be efficiently improved. Further, because an amount of the metal material, for example, silver (Ag) used to form the back electrode current collectors may decrease, the manufacturing cost of the solar cell module may be reduced.

When the interconnector is attached to the back electrode and the back electrode current collector so that a portion of the conductive particles of the conductive adhesive film is embedded in the interconnector and one of the back electrode and the back electrode current collector, a contact area between the conductive particles and the interconnector and/or a contact area between the conductive particles and one of the back electrode and the back electrode current collector increase. Hence, the efficiency and the reliability of the current transfer are improved.

Further, the tabbing process may be performed at a low temperature due to the use of the conductive adhesive film.

A related art tabbing process using the solder is performed at a temperature equal to or higher than about 220° C. On the other hand, because the tabbing process using the conductive adhesive film uses not the soldering method but a bonding method, the tabbing process may be performed at a temperature equal to or lower than about 180° C.

Thus, a bowing phenomenon of the substrate generated in the tabbing process may be greatly reduced, compared with the related art tabbing process.

For example, when a thickness of the substrate is about 200 μm, a bowing amount of the substrate is equal to or greater than about 2.1 mm in the related art tabbing process for melting flux using a hot air. On the other hand, a bowing amount of the substrate is about 0.5 mm in the tabbing process using the conductive adhesive film.

The bowing amount of the substrate may be expressed by a difference between heights of a middle portion and a peripheral portion of the back surface of the substrate.

The bowing phenomenon of the substrate is greatly generated as the thickness of the substrate decreases. For example, when the thickness of the substrate is about 80 μm, the bowing amount of the substrate is equal to or greater than about 14 mm in the related art tabbing process. On the other hand, the bowing amount of the substrate is about 1.8 mm in the tabbing process using the conductive adhesive film.

When the bowing amount of the substrate exceeds a predetermined value, for example, about 2.5 mm, a crack of the substrate or bubbles may be generated in the solar cell module in a subsequent lamination process. Therefore, it is impossible to use a thin substrate in the solar cell module manufactured using the related art tabbing process.

On the other hand, the tabbing process using the conductive adhesive film may greatly reduce the bowing amount of the substrate, compared with the related art tabbing process. Hence, the thin substrate may be used in the solar cell module.

For example, the substrate having the thickness of about 80 μm to 180 μm may be used in the tabbing process using the conductive adhesive film. Thus, the material cost may be reduced because of a reduction in the thickness of the substrate.

The related art tabbing process using the solder may generate the crack at an interface between the back electrode current collector and the interconnector or may generate a peeling phenomenon between several materials inside a solder of the interconnector, thereby reducing the output of the solar cell module. On the other hand, the tabbing process using the conductive adhesive film may solve the above-described problems. Thus, the reliability of the solar cell module may be maintained for a long time.

Further, because the solder is not used in the tabbing process using the conductive adhesive film, an adhesive strength may be uniformly held, and a misalignment may be prevented or reduced. Hence, a reduction in the output of the solar cell module may be prevented or reduced.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is an exploded perspective view of a solar cell module according to an example embodiment of the invention;

FIG. 2 is a side view showing an electrical connection relationship of a solar cell module shown in FIG. 1;

FIG. 3 is an exploded perspective view of a main part of a solar cell module according to a first embodiment of the invention;

FIG. 4 is a plane view of a back surface of a substrate showing a back electrode part;

FIG. 5 is a plane view showing an assembly state of a back surface of a substrate in a solar cell module shown in FIG. 3;

FIG. 6 is a cross-sectional view taken along line VI-VI of FIG. 5;

FIG. 7 is a cross-sectional view taken along line VII-VII of FIG. 5;

FIG. 8 is a cross-sectional view showing a modified embodiment of FIG. 7;

FIG. 9 is a plane view showing an assembly state of a back surface of a substrate in a solar cell module according to a second embodiment of the invention;

FIG. 10 is a cross-sectional view taken along line X-X of FIG. 9; and

FIG. 11 is an exploded perspective view of a main part of a solar cell module according to a third embodiment of the invention.

### DETAILED DESCRIPTION OF THE EMBODIMENTS

Reference will now be made in detail embodiments of the invention examples of which are illustrated in the accompanying drawings. Since the present invention may be modified in various ways and may have various forms, specific embodiments are illustrated in the drawings and are described in detail in the present specification. However, it should be understood that the present invention are not limited to specific disclosed embodiments, but include all modifications, equivalents and substitutes included within the spirit and technical scope of the present invention.

The terms ‘first’, ‘second’, etc., may be used to describe various components, but the components are not limited by such terms. The terms are used only for the purpose of distinguishing one component from other components.

For example, a first component may be designated as a second component without departing from the scope of the present invention. In the same manner, the second component may be designated as the first component.

The term “and/or” encompasses both combinations of the plurality of related items disclosed and any item from among the plurality of related items disclosed.

When an arbitrary component is described as “being connected to” or “being linked to” another component, this should be understood to mean that still another component(s) may exist between them, although the arbitrary component may be directly connected to, or linked to, the second component.

On the other hands, when an arbitrary component is described as “being directly connected to” or “being directly linked to” another component, this should be understood to mean that no component exists between them.

The terms used in the present application are used to describe only specific embodiments or examples, and are not intended to limit the present invention. A singular expression can include a plural expression as long as it does not have an apparently different meaning in context.

In the present application, the terms “include” and “have” should be understood to be intended to designate that illustrated features, numbers, steps, operations, components, parts or combinations thereof exist and not to preclude the existence of one or more different features, numbers, steps, operations, components, parts or combinations thereof, or the possibility of the addition thereof.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Unless otherwise specified, all of the terms which are used herein, including the technical or scientific terms, have the same meanings as those that are generally understood by a person having ordinary knowledge in the art to which the present invention pertains.

The terms defined in a generally used dictionary must be understood to have meanings identical to those used in the context of a related art, and are not to be construed to have ideal or excessively formal meanings unless they are obviously specified in the present application.

The following example embodiments of the invention are provided to those skilled in the art in order to describe the present invention more completely. Accordingly, shapes and sizes of elements shown in the drawings may be exaggerated for clarity.

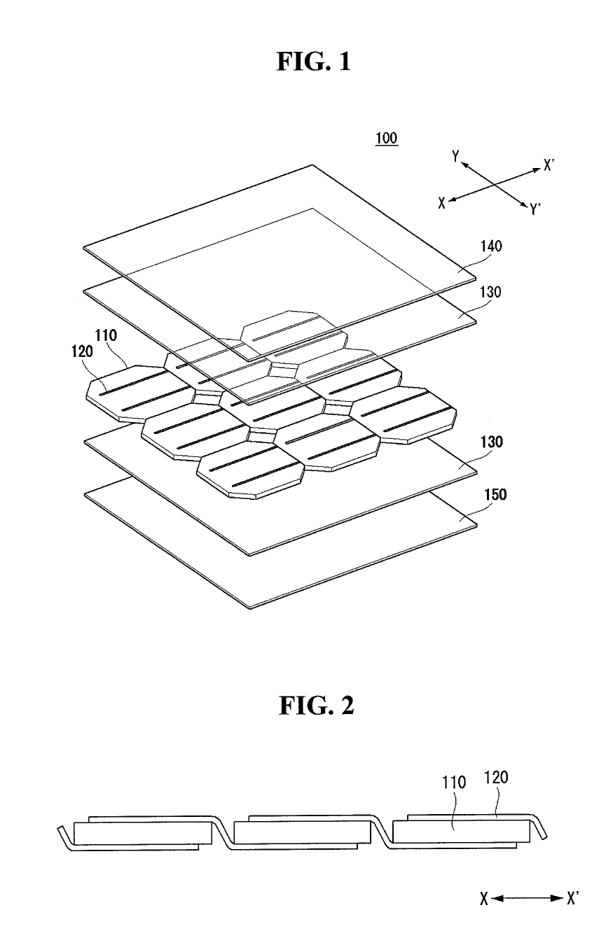

Exemplary embodiments of the invention will be described with reference to FIGS. 1 to 11.

FIG. 1 is an exploded perspective view of a solar cell module according to an example embodiment of the invention. FIG. 2 is a side view showing an electrical connection relationship of the solar cell module shown in FIG. 1.

As shown in FIGS. 1 and 2, a solar cell module 100 according to the embodiment of the invention includes a plurality of solar cells 110, interconnectors 120 for electrically connecting the solar cells 110 to one another, protective layers 130 for protecting the solar cells 110, a transparent member 140 positioned on the protective layer 130 on front surfaces of the solar cells 110, and a back sheet 150 which is positioned under the protective layer 130 on back surfaces of the solar cells 110 and is formed of an opaque material.

The back sheet 150 prevents moisture and oxygen from penetrating into a back surface of the solar cell module 100, thereby protecting the solar cells 110 from an external environment. The back sheet 150 may have a multi-layered structure including a moisture/oxygen penetrating prevention layer, a chemical corrosion prevention layer, an insulation layer, etc.

A lamination process is performed on the protective layers 130 in a state where the protective layers 130 are respectively positioned on and under the solar cells 110 to form an integral body of the protective layers 130 and the solar cells 110. Hence, the protective layers 130 prevent corrosion of the solar cells 110 resulting from the moisture penetration and protect the solar cells 110 from an impact. The protective layers 130 may be formed of ethylene vinyl acetate (EVA) or silicon resin. Other materials may be used.

The transparent member 140 positioned on the protective layer 130 is formed of a tempered glass having a high transmittance and an excellent damage prevention function. The tempered glass may be a low iron tempered glass containing a small amount of iron. The transparent member 140 may have an embossed inner surface so as to increase a scattering effect of light.

An electrical connection structure of the solar cells 110 included in the solar cell module 100 according to the embodiment of the invention is described in detail below with reference to FIG. 2. FIG. 2 is a diagram enlarging a distance between the solar cells 110. In fact, the solar cells 110 are disposed to be separated from one another by a predetermined distance, for example, a narrow distance less than about 3 mm.

The plurality of solar cells 110 included in the solar cell module 100 are arranged in the form of a plurality of strings. In the embodiment disclosed herein, the string refers to the shape where the plurality of solar cells 110 are electrically connected to one another in a state where they are arranged in a row.

The plurality of solar cells 110 arranged on each string are electrically connected to one another using the interconnectors 120.

The interconnector 120 may be formed of a conductive metal of a lead-free material containing lead (Pb) equal to or less than about 1,000 ppm. Alternatively, the interconnector 120 may further include a solder formed of a Pb-containing material coated on the surface of the conductive metal.

In one string, a front electrode part of one of the plurality of solar cells 110, which are positioned adjacent to one another in a first direction X-X′, is electrically connected to a back electrode part of another solar cell 110 adjacent to the one solar cell 110 using the interconnector 120.

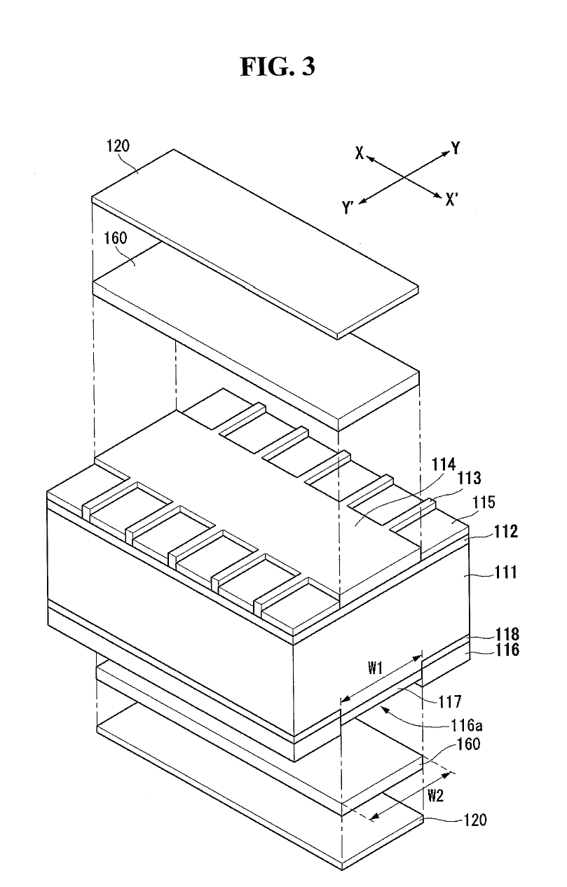

A solar cell module according to a first embodiment of the invention is described in detail below with reference to FIGS. 3 to 7.

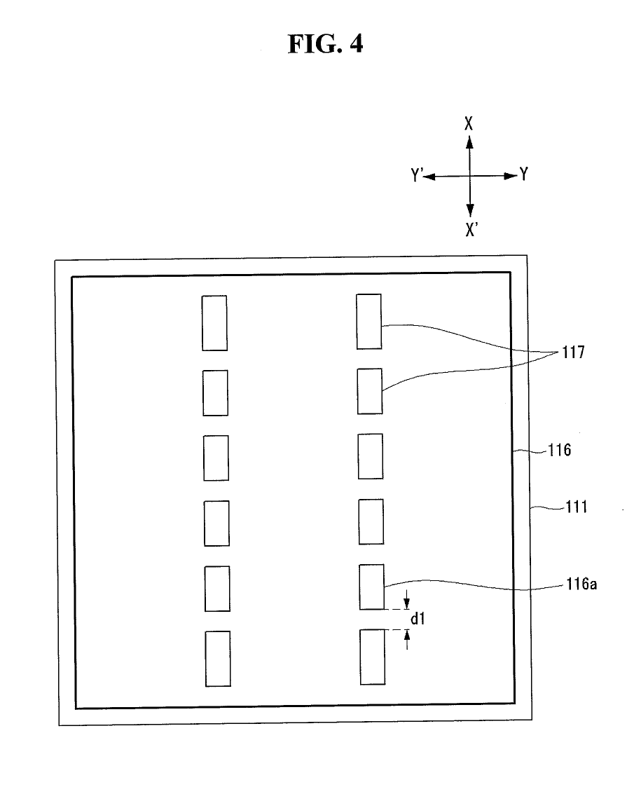

FIG. 3 is an exploded perspective view of a main part of a solar cell module according to a first embodiment of the invention. FIG. 4 is a plane view of a back surface of a substrate showing a back electrode part.

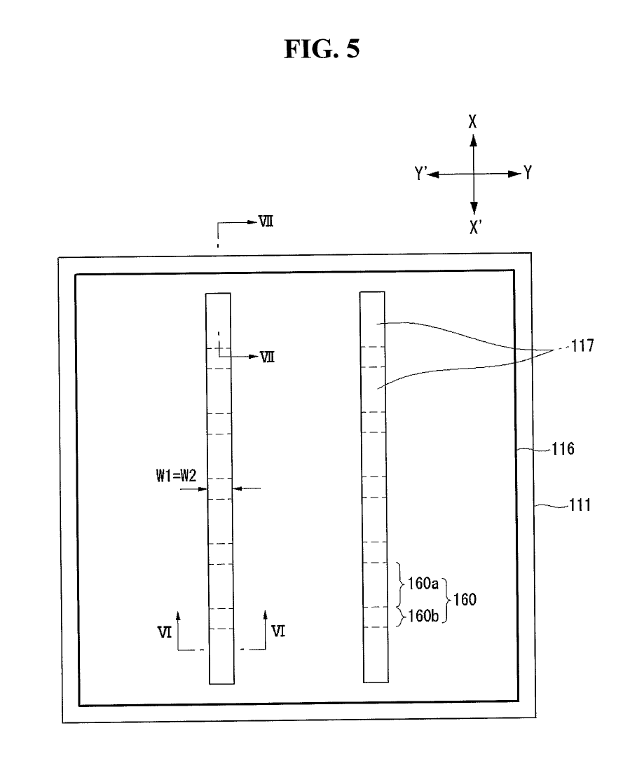

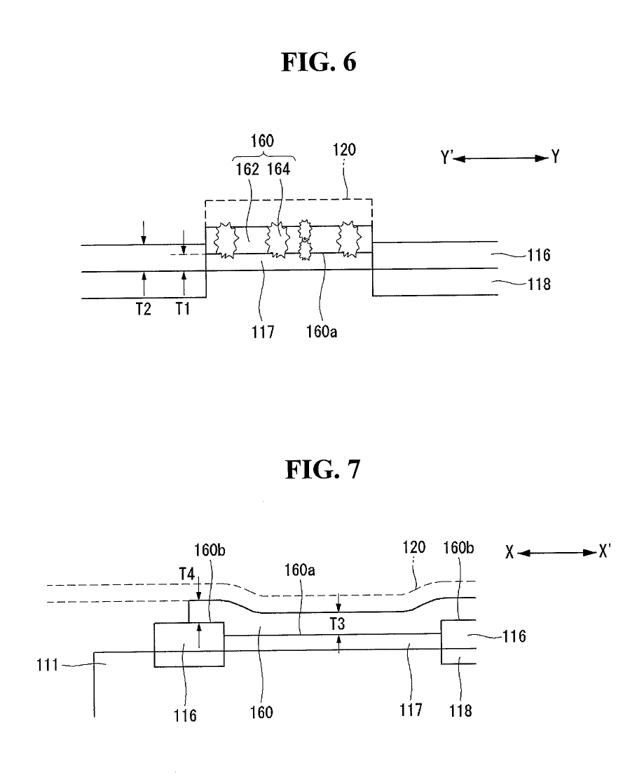

FIG. 5 is a plane view showing an assembly state of a back surface of a substrate in the solar cell module shown in FIG. 3. FIG. 6 is a cross-sectional view taken along line VI-VI of FIG. 5, and FIG. 7 is a cross-sectional view taken along line VII-VII of FIG. 5.

The solar cell 110 according to the first embodiment of the invention may include a substrate 111, an emitter region 112 positioned at a first surface (i.e., a front surface on which light is incident) of the substrate 111, a dielectric layer 115 positioned on the emitter region 112, a plurality of front electrodes 113 and a plurality of front electrode current collectors 114 which are positioned on the emitter region 112 through openings of the dielectric layer 115 and are electrically connected to the emitter region 112, a back electrode 116 and a plurality of back electrode current collectors 117 which are positioned on a second surface (i.e., a back surface opposite the front surface) opposite the first surface of the substrate 111, and a back surface field (BSF) region 118 positioned between the back electrode 116 and the substrate 111.

The substrate 111 is a semiconductor substrate formed of first conductive type silicon, for example, p-type silicon, though not required. Silicon used in the substrate 111 may be single crystal silicon, polycrystalline silicon, or amorphous silicon. When the substrate 111 is of a p-type, the substrate 111 contains impurities of a group III element such as boron (B), gallium (Ga), and indium (In).

The front surface of the substrate 111 may be textured to form a textured surface corresponding to an uneven surface or having uneven characteristics.

When the front surface of the substrate 111 is the textured surface, a reflectance of light incident on the front surface of the substrate 111 is reduced. Further, because both a light incident operation and a light reflection operation are performed on the textured surface of the substrate 111, light is confined in the solar cell 110. Hence, an absorption rate of light increases.

As a result, the efficiency of the solar cell 110 is improved. In addition, because a reflection loss of light incident on the substrate 111 decreases, an amount of light incident on the substrate 111 further increases.

The emitter region 112 is a region doped with impurities of a second conductive type (for example, an n-type) opposite the first conductive type of the substrate 111. The emitter region 112 forms a p-n junction along with the substrate 111.

The emitter region 112 is entirely formed at the inside of the front surface of the substrate 111. If necessary or desired, the emitter region 112 may be formed as a selective emitter region including a heavily doped region and a lightly doped region.

In the embodiment disclosed herein, the meaning of “entirely” includes that the emitter region is formed at an entire area of the front surface of the substrate 111 except a very small area, for example, an edge area of the front surface of the substrate 111.

Accordingly, the emitter region 112 may be entirely formed at the inside of the front surface of the substrate 111. Alternatively, the emitter region 112 may be entirely formed at the inside of the front surface of the substrate 111 except the edge area of the front surface of the substrate 111.

When the emitter region 112 is of the n-type, the emitter region 112 may be formed by doping the substrate 111 with impurities of a group V element such as phosphor (P), arsenic (As), and antimony (Sb).

When energy produced by light incident on the substrate 111 is applied to carriers inside the semiconductors, electrons move to the n-type semiconductor and holes move to the p-type semiconductor. Thus, when the substrate 111 is of the p-type and the emitter region 112 is of the n-type, the holes move to the substrate 111 and the electrons move to the emitter region 112.

Alternatively, the substrate 111 may be of an n-type and/or may be formed of a semiconductor material other than silicon. If the substrate 111 is of the n-type, the substrate 111 may contain impurities of a group V element such as phosphorus (P), arsenic (As), and antimony (Sb).

Because the emitter region 112 forms the p-n junction along with the substrate 111, the emitter region 112 may be of the p-type if the substrate 111 is of the n-type unlike the embodiment described above. In this instance, the electrons may move to the substrate 111, and the holes may move to the emitter region 112.

If the emitter region 112 is of the p-type, the emitter region 112 may be formed by doping the substrate 111 with impurities of a group III element such as boron (B), gallium (Ga), and indium (In).

The dielectric layer 115 on the emitter region 112 may have a single-layered structure including one material of silicon nitride (SiNx), silicon dioxide (SiO₂), silicon oxynitride (SiOxNy), and titanium dioxide (TiO₂), or a multi-layered structure including at least two of the materials.

The dielectric layer 115 may serve as an anti-reflection layer, which reduces a reflectance of light incident on the solar cell 110 and increases selectivity of light of a predetermined wavelength band to thereby increase the efficiency of the solar cell 110. If the dielectric layer 115 has the multi-layered structure, the dielectric layer 115 may include a lower layer performing a passivation function and an upper layer performing an anti-reflection function.

The plurality of front electrodes 113 positioned on the front surface of the substrate 111 may be referred to as finger electrodes, and are positioned on the emitter region 112 exposed through the openings of the dielectric layer 115.

Hence, an entire lower surface of each front electrode 113 directly contacts the emitter region 112, and thus the front electrodes 113 are electrically connected to the emitter region 112.

In the embodiment disclosed herein, the lower surface of the front electrode 113 refers to the surface facing the emitter region 112.

If the emitter region 112 is formed as the selective emitter region, the entire lower surface of the front electrode 113 may directly contact the heavily doped region of the emitter region 112.

The front electrodes 113 extend in a second direction Y-Y′ orthogonal to the first direction X-X′ to be separated from one another.

The front electrodes 113 having the above-described configuration collect carriers (e.g., electrons) moving to the emitter region 112.

The front electrodes 113 are formed of at least one conductive material. The conductive material may be at least one selected from the group consisting of nickel (Ni), copper (Cu), silver (Ag), aluminum (Al), tin (Sn), zinc (Zn), indium (In), titanium (Ti), gold (Au), and a combination thereof. Other conductive materials may be used for the front electrodes 113.

For example, the front electrodes 113 may be formed of a conductive paste containing silver (Ag). In this instance, the front electrodes 113 may be electrically connected to the emitter region 112 by applying the Ag paste to the dielectric layer 115 through a screen printing process and firing the substrate 111 at a temperature of about 750° C. to 800° C.

The electrical connection between the front electrodes 113 and the emitter region 112 is performed by etching the dielectric layer 115 using an etching component (for example, lead oxide (PbO)) contained in the conductive paste (for example, the Ag paste) in the firing process and then bringing Ag particles of the Ag paste into contact with the emitter region 112.

At least two front electrode current collectors 114 are formed on the emitter region 112 and extend in a direction (i.e., the first direction X-X′) crossing the front electrodes 113.

The front electrode current collectors 114 may be formed of the same material as the front electrodes 113 and are electrically and physically connected to the emitter region 112 and the front electrodes 113. Thus, the front electrode current collectors 114 output carriers (for example, electrons) transferred from the front electrodes 113 to an external device.

The front electrode current collectors 114 may be electrically connected to the emitter region 112 by applying and patterning a conductive paste containing silver (Ag) to the dielectric layer 115 and firing the substrate 111 in the same manner as the front electrodes 113.

In the embodiment of the invention, the front electrodes 113 and the front electrode current collectors 114 constitute a front electrode part.

As shown in FIG. 4, the plurality of back electrode current collectors 117 are positioned on the second surface, i.e., the back surface of the substrate 111 at a location corresponding to the front electrode current collectors 114. The plurality of back electrode current collectors 117 are formed in an island shape to be separated from one another by a first distance D1 along the first direction X-X′ crossing the front electrodes 113.

The back electrode current collectors 117 are formed using the same conductive paste as the front electrodes 113 and the front electrode current collectors 114 and are electrically connected to the back surface field region 118.

The back electrode current collectors 117 may be directly connected to the back electrode 116. Thus, the back electrode current collectors 117 output carriers (for example, holes) transferred from the back electrode 116 to the external device.

The back electrode 116 positioned on the back surface of the substrate 111 includes a plurality of openings 116a exposing the back electrode current collectors 117. In fact, the back electrode 116 is formed in a sheet shape covering the entire back surface of the substrate 111 except the openings 116a.

In the embodiment disclosed herein, the fact that the back electrode 116 covers the entire back surface of the substrate 111 except the openings 116a includes the case where the back electrode 116 is formed on the entire back surface of the substrate 111 except the openings 116a, in which the back electrode current collectors 117 are positioned, or the case where the back electrode 116 is formed on the entire back surface of the substrate 111 except the openings 116a, in which the back electrode current collectors 117 are positioned, and an edge area of the back surface of the substrate 111.

In the embodiment of the invention, the back electrode 116 and the back electrode current collectors 117 constitute a back electrode part.

The back electrode 116 is formed of at least one conductive material. The conductive material may be at least one selected from the group consisting of nickel (Ni), copper (Cu), silver (Ag), aluminum (Al), tin (Sn), zinc (Zn), indium (In), titanium (Ti), gold (Au), and a combination thereof. Other conductive materials may be used for the back electrode 116.

The back electrode 116 may be formed of a conductive material, for example, aluminum (Al) different from the back electrode current collectors 117, so as to form the back surface field region 118 at the inside of the back surface of the substrate 111.

As described above, a reason why the back electrode 116 is formed of aluminum (Al) is that impurities contained in a conductive paste containing aluminum (Al) used as a conductive paste for the back electrode 116 are diffused into the inside of the back surface of the substrate 111 to automatically form the back surface field region 118 when the conductive paste containing aluminum (Al) is printed on the back surface of the substrate 111 and then is fired.

Accordingly, when the back electrode 116 is formed using the conductive paste containing aluminum (Al), injection and/or diffusion processes of impurities for forming the back surface field region 118 may be omitted.

As shown in FIG. 7, the back electrode 116 and the back electrode current collector 117 have different thicknesses. For example (see FIG. 6), a thickness T1 of the back electrode current collector 117 may be less than a thickness T2 of the back electrode 116. In this instance, a difference (T2−T1) between the thickness T2 of the back electrode 116 and the thickness T1 of the back electrode current collector 117 may be about 5 μm to 25 μm.

In the above-described structure of the back electrode part, because the thickness T1 of the back electrode current collector 117 is less than the thickness T2 of the back electrode 116 and the back electrode current collectors 117 are formed in the island shape, an amount of silver (Ag) used may be reduced. Hence, the manufacturing cost of the solar cell module may be reduced.

In the process for firing the conductive paste for the back electrode 116, the back surface field region 118 formed at the inside of the back surface of the substrate 111 is a region (for example, a p⁺-type region) which is more heavily doped than the substrate 111 with impurities of the same conductive type as the substrate 111.

The back surface field region 118 serves as a potential barrier at the back surface of the substrate 111. Thus, because the back surface field region 118 prevents or reduces a recombination and/or a disappearance of electrons and holes at and around the back surface of the substrate 111, the efficiency of the solar cell 110 is improved.

In the solar cell 110 having the above-described configuration, a conductive adhesive film 160 is positioned on the front electrode current collectors 114 at the front surface of the substrate 111 in a direction (i.e., the first direction X-X′) parallel to the front electrode current collectors 114.

Further, the conductive adhesive film 160 is positioned on the back electrode 116 and the back electrode current collectors 117 at the back surface of the substrate 111 in the first direction X-X′.

FIG. 3 shows that one conductive adhesive film 160 is positioned on each of the front surface and the back surface of the substrate 111. However, as shown in FIG. 5, the conductive adhesive films 160 having the same number as the interconnectors 120 may be positioned on each of the front surface and the back surface of the substrate 111.

As shown in FIG. 6, the conductive adhesive film 160 includes a resin 162 and a plurality of conductive particles 164 distributed in the resin 162. A material of the resin 162 is not particularly limited as long as it has the adhesive property. It is preferable, but not required, that a thermosetting resin is used for the resin 162 so as to increase the adhesive reliability.

The thermosetting resin may use at least one selected among epoxy resin, phenoxy resin, acryl resin, polyimide resin, and polycarbonate resin.

The resin 162 may contain a predetermined material, for example, a known curing agent and a known curing accelerator, in addition to the thermosetting resin. For example, the resin 162 may contain a reforming material, such as a silane-based coupling agent, a titanate-based coupling agent, and an aluminate-based coupling agent, so as to improve an adhesive strength between the front electrode current collectors 114 and the interconnector 120 and an adhesive strength between the back electrode current collectors 117 and the interconnector 120.

The resin 162 may contain a dispersing agent, for example, calcium phosphate and calcium carbonate, so as to improve the dispersibility of the conductive particles 164. The resin 162 may contain a rubber component, such as acrylic rubber, silicon rubber, and urethane rubber, so as to control the modulus of elasticity of the conductive adhesive film 160.

A material of the conductive particles 164 is not particularly limited as long as it has the conductivity.

As shown in FIG. 6, the conductive particles 164 may include radical metal particles of various sizes. In the embodiment disclosed herein, ‘the radical metal particles’ are metal particles of a nearly spherical shape which contain at least one metal selected among copper (Cu), silver (Ag), gold (Au), iron (Fe), nickel (Ni), lead (Pb), zinc (Zn), cobalt (Co), titanium (Ti), and magnesium (Mg) as the main component and each have a plurality of protrusions non-uniformly formed on its surface.

It is preferable, but not required, that the conductive adhesive film 160 includes at least one radical metal particle having the size greater than a thickness of the resin 162, so that a current smoothly flows between the front electrode current collectors 114 and the interconnector 120 and between the back electrode current collectors 117 and the interconnector 120.

According to the above-described configuration of the conductive adhesive film 160, a portion of the radical metal particle having the size greater than the thickness of the resin 162 is embedded in the back electrode current collector 117 and/or the interconnector 120.

In the same manner as this, a portion of the radical metal particle having the size greater than the thickness of the resin 162 is embedded in the front electrode current collector 114 and/or the interconnector 120.

Hence, a contact area between the radical metal particle and the current collectors 114 and 117 and/or a contact area between the radical metal particle and the interconnector 120 increase, and thus contact resistances therebetween are reduced. The reduction in the contact resistances makes the current flow between the current collectors 114 and 117 and the interconnector 120 smooth.

So far, the embodiment of the invention described that the radical metal particles are used as the conductive particles 164. However, the conductive particles 164 may be metal-coated resin particles containing at least one metal selected among copper (Cu), silver (Ag), gold (Au), iron (Fe), nickel (Ni), lead (Pb), zinc (Zn), cobalt (Co), titanium (Ti), and magnesium (Mg) as the main component.

When the conductive particles 164 are the metal-coated resin particles, each of the conductive particles 164 may have a circle shape or an oval shape.

The conductive particles 164 may physically contact one another.

It is preferable, but not required, that a composition amount of the conductive particles 164 distributed in the resin 162 is about 0.5% to 20% based on the total volume of the conductive adhesive film 160 in consideration of the connection reliability after the resin 162 is cured.

When the composition amount of the conductive particles 164 is less than about 0.5%, the current may not smoothly flow because of a reduction in a physical contact area between the current collectors 114 and 117 and the conductive particles 164. When the composition amount of the conductive particles 164 is greater than about 20%, the adhesive strength between the current collectors 114 and 117 and the interconnector 120 may be reduced because a composition amount of the resin 162 relatively decreases.

The conductive adhesive film 160 is attached to the front electrode current collectors 114 in a direction parallel to the front electrode current collectors 114 and is attached to the back electrode current collectors 117 in a direction parallel to the back electrode current collectors 117.

A tabbing process includes a preliminary bonding stage for preliminarily bonding the conductive adhesive film 160 to the current collectors 114 and 117, an alignment and preliminary fixing stage for aligning and preliminarily fixing the interconnector 120 to the conductive adhesive film 160, and a final bonding stage for finally bonding the interconnector 120, the conductive adhesive film 160, and the current collectors 114 and 117.

When the tabbing process is performed using the conductive adhesive film 160, a heating temperature and a pressure of the tabbing process are not particularly limited as long as they are set within the range capable of securing the electrical connection and maintaining the adhesive strength.

For example, the heating temperature in the preliminary bonding stage may be set to be equal to or lower than about 100° C., and the heating temperature in the final bonding stage may be set to a curing temperature of the resin 162, for example, about 140° C. to 180° C.

Further, the pressure in the preliminary bonding stage may be set to about 1 MPa. The pressure in the final bonding stage may be set to a range, for example, about 2 MPa to 3 MPa capable of sufficiently attaching the front electrode current collectors 114, the back electrode current collectors 117, and the interconnector 120 to the conductive adhesive film 160.

In this instance, the pressure may be set so that at least a portion of the conductive particles 164 is embedded in the current collectors 114 and 117 and/or the interconnector 120.

Time required to apply the heat and the pressure in the preliminary bonding stage may be set to about 5 seconds. Time required to apply the heat and the pressure in the final bonding stage may be set to the extent (for example, about 10 seconds) that the front electrode current collectors 114, the back electrode current collectors 117, and the interconnector 120, etc., are not damaged or deformed by the heat.

The substrate 111 may be bowed because of the heat applied in the preliminary bonding stage and the final bonding stage.

According to a result of an experiment, which was conducted by the present inventors and measured a bowing amount of the substrate depending on a thickness of the substrate in the tabbing process using the conductive adhesive film according to the embodiment of the invention and a related art tabbing process using hot air, when the thickness of the substrate was about 200 μm, a bowing amount of the substrate was equal to or greater than about 2.1 mm in the related art tabbing process for melting flux using hot air. On the other hand, the bowing amount of the substrate was about 0.5 mm in the tabbing process using the conductive adhesive film according to the embodiment of the invention.

In the embodiment disclosed herein, the thickness of the substrate 111 refers to a thickness ranging from the back surface of the substrate 111 to the emitter region 112. The bowing amount of the substrate 111 refers to a difference between heights of a middle portion and a peripheral portion of the back surface of the substrate 111.

The bowing amount of the substrate increases as the thickness of the substrate decreases. For example, when the thickness of the substrate was about 80 μm, the bowing amount of the substrate was equal to or greater than about 14 mm in the related art tabbing process for melting flux using hot air. On the other hand, the bowing amount of the substrate was about 1.8 mm in the tabbing process using the conductive adhesive film according to the embodiment of the invention.

According to the result of the experiment, the bowing amount of the substrate generated when the thickness of the substrate was about 80 μm in the tabbing process using the conductive adhesive film according to the embodiment of the invention was similar to the bowing amount of the substrate generated when the thickness of the substrate was about 200 μm in the related art tabbing process using hot air.

When the bowing amount of the substrate exceeds a predetermined value, for example, about 2.5 mm, a crack may be generated in the substrate or bubbles may be generated in the solar cell module in a subsequent lamination process. Therefore, it is impossible to use the thin substrate in the solar cell module manufactured using the related art tabbing process.

On the other hand, the tabbing process using the conductive adhesive film according to the embodiment of the invention may greatly reduce the bowing amount of the substrate, compared with the related art tabbing process. Hence, the thin substrate may be used in the embodiment of the invention.

For example, the substrate having the thickness of about 80 μm to 180 μm may be used in the tabbing process according to the embodiment of the invention. Because the material cost of the solar cell module is reduced as the thickness of the substrate decreases, the thickness of the substrate may be equal to or less than about 180 μm in the embodiment of the invention using the conductive adhesive film.

The conductive adhesive film 160 alternately includes a first portion 160a contacting the back electrode current collector 117 and a second portion 160b contacting the back electrode 116 based on the first direction X-X′.

In the first embodiment of the invention shown in FIGS. 3 to 7, a width W2 of the conductive adhesive film 160 measured in the second direction Y-Y′ is substantially equal to a width W1 of the back electrode current collector 117, and a length of the conductive adhesive film 160 measured in the first direction X-X′ is longer than a length of the back electrode current collector 117

Accordingly, the second portion 160b of the conductive adhesive film 160 is positioned in a space between the back electrode current collectors 117 in the first direction X-X′.

A thickness T3 of the first portion 160a is substantially equal to a thickness T4 of the second portion 160b.

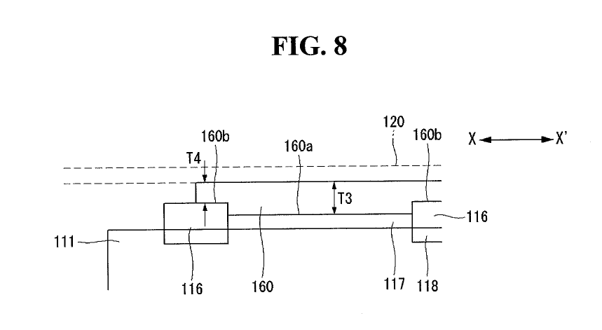

On the other hand, as shown in FIG. 8, the thickness T3 of the first portion 160a may be different from the thickness T4 of the second portion 160b.

When the thickness T1 of the back electrode current collector 117 is less than the thickness T2 of the back electrode 116, the thickness T3 of the first portion 160a contacting the back electrode current collector 117 is greater than the thickness T4 of the second portion 160b contacting the back electrode 116.

In this instance, when the difference (T2−T1) between the thickness T2 of the back electrode 116 and the thickness T1 of the back electrode current collector 117 is about 5 μm to 25 μm, a difference (T3−T4) between the thickness T3 of the first portion 160a and the thickness T4 of the second portion 160b may be about 5 μm to 25 μm.

According to the above-described configuration, because the resin 162 of the conductive adhesive film 160 has the flexibility by the heat applied in the final bonding stage, a portion having a height difference between the back electrode 116 and the back electrode current collector 117 is filled with the conductive adhesive film 160 as shown in FIGS. 7 and 8. Thus, there is not a non-contact portion between the back electrode current collector 117 and the interconnector 120. Hence, a reduction in a current collection efficiency of the solar cell module may be prevented or reduced.

Further, because the adhesive characteristic of the conductive adhesive film 160 scarcely changes depending on kinds of metals to be attached unlike tin (Sn)-based solder, the conductive adhesive film 160 is satisfactorily attached to the back electrode current collector 117 formed using the conductive paste containing silver (Ag) and the back electrode 116 formed using the conductive paste containing aluminum (Al).

Accordingly, even when the plurality of back electrode current collectors 117 are positioned in the island shape along a longitudinal direction of the conductive adhesive film 160 in an area to which the conductive adhesive film 160 is attached, the current collection efficiency of the solar cell module may be efficiently improved. Further, because an amount of the metal material, for example, silver (Ag) used to form the back electrode current collectors 117 decreases, the manufacturing cost of the solar cell module may be reduced.

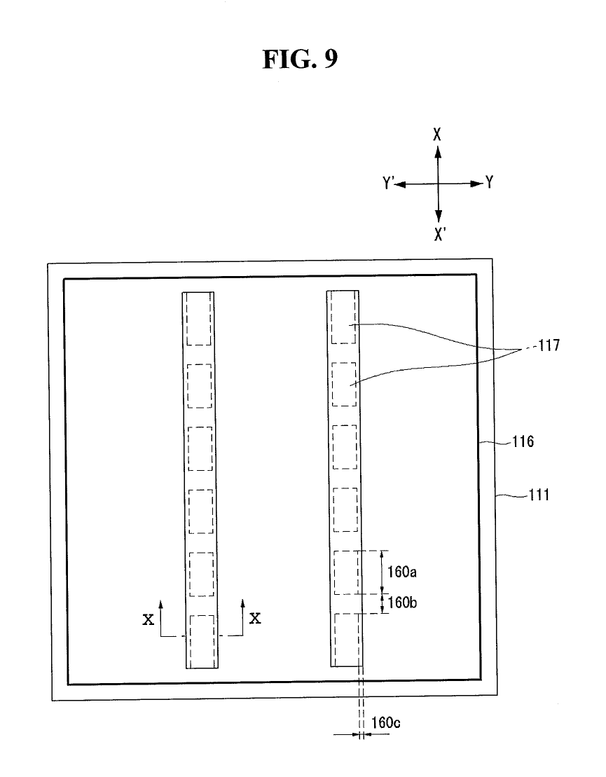

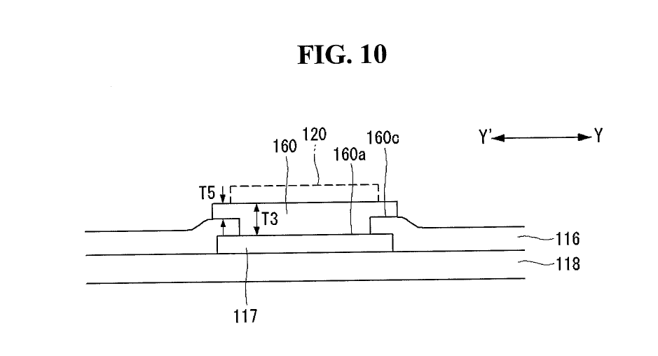

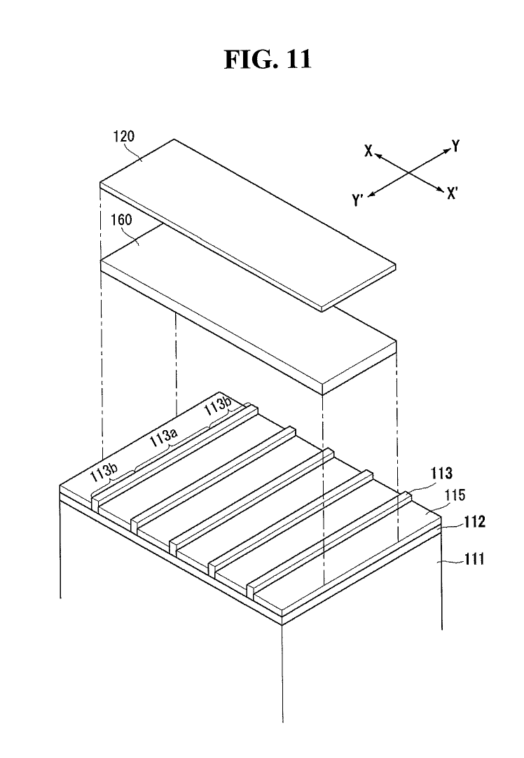

FIG. 9 is a plane view showing an assembly state of a back surface of a substrate in a solar cell module according to a second embodiment of the invention. FIG. 10 is a cross-sectional view taken along line X-X of FIG. 9.

A back electrode 116 and back electrode current collectors 117 may overlap each other at edges of openings.

For example, as shown in FIGS. 9 and 10, when the back electrode 116 is formed on a back surface of a substrate 111 after the back electrode current collectors 117 are formed on the back surface of the substrate 111, a portion of the back electrode 116 may cover a portion of an edge of the back electrode current collector 117.

In this instance, a back surface field region 118 formed using a conductive paste for forming the back electrode 116 is formed only in a formation area of the back electrode 116 as in the first embodiment of the invention shown in FIGS. 3 to 8.

On the other hand, when the back electrode current collectors 117 are formed on the back surface of the substrate 111 after the back electrode 116 of a sheet shape is formed on the back surface of the substrate 111, a portion of the edges of the back electrode current collectors 117 may cover an edge of an opening of the back electrode 116.

In this instance, as shown in FIG. 10, the back surface field region 118 is formed in both the formation area of the back electrode 116 and a formation area of the opening of the back electrode 116. Thus, the back surface field region 118 is entirely formed at the inside of the back surface of the substrate 111.

According to the above-described structure, the back electrode 116 and the back electrode current collectors 117 directly contact each other in an overlap area therebetween. Therefore, carriers collected by the back electrode 116 are more efficiently transferred to the back electrode current collectors 117.

In the solar cell having the above-described structure, a width of a conductive adhesive film 160 measured in a second direction Y-Y′ is greater than a width of an opening 116a of the back electrode 116.

Accordingly, the conductive adhesive film 160 in a first direction X-X′ alternately includes a first portion 160a contacting the back electrode current collector 117 and a second portion 160b contacting the back electrode 116 in an area between the back electrode current collectors 117. The conductive adhesive film 160 in the second direction Y-Y′ further includes a third portion 160c contacting the back electrode 116 on at least one side of the first portion 160a.

In this instance, a thickness T3 of the first portion 160a of the conductive adhesive film 160 may be greater than a thickness T5 of the third portion 160c of the conductive adhesive film 160.

In the embodiment disclosed herein, a width of an interconnector 120 is not particularly limited, but may be equal to or greater than a width of the conductive adhesive film 160.

So far, a connection structure of the back electrode current collectors 117, the conductive adhesive film 160, and the interconnector 120 was described. However, the connection structure may be applied to a connection structure of the front electrode current collectors 114, the conductive adhesive film 160, and the interconnector 120.

A solar cell module according to a third embodiment of the invention is described below with reference to FIG. 11. Since a structure of a back electrode part and a tabbing structure in the third embodiment of the invention are substantially the same as the first and/or second embodiments of the invention, a further description may be briefly made or may be entirely omitted. A structure of a front electrode part and a tabbing structure are described below.

Structures and components identical or equivalent to those described in the first and second embodiments are designated with the same reference numerals in the third embodiment of the invention, and a further description may be briefly made or may be entirely omitted.

As shown in FIG. 11, only a plurality of front electrodes 113 are positioned on an emitter region 112 of a substrate 111, unlike the first embodiment. Namely, a front electrode current collector is not formed in the third embodiment of the invention.

A plurality of conductive adhesive films 160 are positioned on a front surface of the substrate 111 in a direction crossing the front electrodes 113 and are attached to a portion of each of the front electrodes 113 in the direction crossing the front electrodes 113. Thus, a portion of the conductive adhesive film 160 directly contacts a portion of the front electrode 113, and a remaining portion of the conductive adhesive film 160 directly contacts a dielectric layer 115.

Hereinafter, the portion of the front electrode 113, to which the conductive adhesive film 160 is attached, is referred to as a first portion 113a, and the portion of the front electrode 113, to which the conductive adhesive film 160 is not attached, is referred to as a second portion 113b.

An interconnector 120 is attached to a front surface of the conductive adhesive film 160 attached to the first portion 113a of the front electrode 113 in the same direction as the conductive adhesive film 160. The interconnector 120 of one solar cell is attached to a back surface of a substrate of another solar cell adjacent to the one solar cell.

The conductive adhesive film 160 may have a thickness greater than a protruding thickness of the front electrode 113, so as to satisfactorily attach the interconnector 120 to the conductive adhesive film 160. In this instance, because the front surface of the conductive adhesive film 160 is a flat surface, the interconnector 120 is satisfactorily attached to the conductive adhesive film 160.

In the embodiment disclosed herein, “the protruding thickness” of the front electrode 113 refers to a thickness of the front electrode 113 protruding from the dielectric layer 115 in the total thickness of the front electrode 113.

Because the front electrode 113 generally has a thickness equal to or less than about 15 μm, the protruding thickness of the front electrode 113 is less than about 15 μm. Thus, a thickness of the conductive adhesive film 160 may be properly selected in the range of about 15 μm to 60 μm depending on the desired specifications of the solar cell.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell module comprising:
a plurality of solar cells each including a back electrode part including a substrate, a plurality of back electrode current collectors of an island shape, which are positioned on a back surface of the substrate and are separated from one another by a first distance along a first direction, and a back electrode which includes a plurality of openings exposing the plurality of back electrode current collectors and has a sheet shape covering the entire back surface of the substrate;
an interconnector configured to electrically connect adjacent solar cells; and
a conductive adhesive film configured to attach the interconnector to the solar cells,
wherein the back electrode current collectors and the back electrode are formed of different metal materials, and
wherein the conductive adhesive film alternately includes a first portion contacting the back electrode current collector and a second portion contacting the back electrode based on the first direction.

2. The solar cell module of claim 1, wherein the back electrode and the back electrode current collectors do not overlap each other at edges of the openings of the back electrode.

3. The solar cell module of claim 2, wherein a difference between a thickness of the back electrode and a thickness of the back electrode current collector is about 5 μm to 25 μm.

4. The solar cell module of claim 3, wherein a thickness of the first portion of the conductive adhesive film is greater than a thickness of the second portion of the conductive adhesive film.

5. The solar cell module of claim 4, wherein a difference between the thicknesses of the first portion and the second portion of the conductive adhesive film is about 5 μm to 25 μm.

6. The solar cell module of claim 2, wherein the conductive adhesive film further includes a third portion contacting the back electrode on at least one side of the first portion in a second direction orthogonal to the first direction.

7. The solar cell module of claim 1, wherein the back electrode and the back electrode current collectors overlap each other at edges of the openings of the back electrode.

8. The solar cell module of claim 7, wherein a difference between a thickness of the back electrode and a thickness of the back electrode current collector is about 5 μm to 25 μm.

9. The solar cell module of claim 8, wherein a thickness of the first portion of the conductive adhesive film is greater than a thickness of the second portion of the conductive adhesive film.

10. The solar cell module of claim 9, wherein a difference between the thicknesses of the first portion and the second portion of the conductive adhesive film is about 5 μm to 25 μm.

11. The solar cell module of claim 1, wherein each of the plurality of solar cells further includes a back surface field region positioned at the back surface of the substrate.

12. The solar cell module of claim 11, wherein the back surface field region is positioned only in a formation area of the back electrode and is not positioned in a formation area of the openings of the back electrode.

13. The solar cell module of claim 11, wherein the back surface field region is positioned in a formation area of the back electrode and a formation area of the openings of the back electrode.

14. The solar cell module of claim 11, wherein the conductive adhesive film includes a resin and a plurality of conductive particles distributed in the resin, and the plurality of conductive particles directly contact the interconnector and one of the back electrode and the back electrode current collector.

15. The solar cell module of claim 11, wherein each of the plurality of solar cells further includes an emitter region positioned at an entire front surface of the substrate, a front electrode part electrically connected to the emitter region, and a dielectric layer positioned on the emitter region, and
wherein the front electrode part includes a plurality of finger electrodes extending in a second direction orthogonal to the first direction, and an entire lower surface of each finger electrode directly contacts the emitter region.

16. The solar cell module of claim 15, wherein the front electrode part further includes a front electrode current collector which extends in the first direction and is connected to the plurality of finger electrodes, and an entire lower surface of the front electrode current collector directly contacts the emitter region.

17. The solar cell module of claim 1, wherein the plurality of openings respectively correspond to the plurality of back electrode current collectors.
